(19) United States
(12) Patent Application Publication
(10) Pub. No.: US 2019/0259905 A1
(43) Pub. Date: Aug. 22, 2019

(54) Method For Passivating A Surface Of A Semiconductor Material And Semiconductor Substrate

(71) Applicant: CENTROTHERM INTERNATIONAL AG, BLAUBEUREN (DE)

(72) Inventors: JENS-UWE FUCHS, NEU-ULM (DE); WOLFGANG JOOSS, KONSTANZ (DE); THOMAS PERNAU, BLAUBEUREN (DE); VIET XUAN NGUYEN, EHINGEN (DE)

(21) Appl. No.: 16/334,080

(22) PCT Filed: Sep. 15, 2017
(86) PCT No.: PCT/DE2017/100790

§ 371 Date: Mar. 18, 2019

(30) Foreign Application Priority Data
Sep. 16, 2016 (DE) 10 2016 117 541.2

(51) Int. Cl. H01L 31/18; H01L 23/31; H01L 21/02; H01L 31/0216

(52) U.S. Cl. CPC H01L 31/1868; H01L 23/3171; H01L 21/02178; H01L 21/02274; H01L 31/02167; H01L 21/0217; H01L 21/0214; H01L 21/02164; H01L 21/0234; H01L 21/02323

(57) ABSTRACT

A method for passivating a surface of a semiconductor material includes forming a layer stack having an aluminum oxide layer and an outer coating on the surface of the semiconductor material. The aluminum oxide layer and the outer coating are respectively formed in vacuum processes in which a vacuum is present. The vacuum is maintained between the forming of the aluminum oxide layer and the forming of the outer coating. Hydrogen and oxygen are supplied after the forming of the aluminum oxide layer and before the forming of the outer coating. A semiconductor substrate is also provided.

The invention relates to a method for passivating a surface of a semiconductor material. The invention furthermore relates to a semiconductor substrate.

For the passivation of surfaces of semiconductor materials, use is frequently made of layer stacks of dielectric layers, for example layer stacks consisting of an aluminum oxide layer and a silicon nitride layer. These layers are commonly deposited in vacuum processes. To date, the aluminum oxide layer has preferably been formed by the deposition of atomic layers, in English often referred to as Atomic Layer Deposition or ALD for short. By contrast, silicon nitride layers are usually realized by means of plasma-driven vapor depositions, in English commonly referred to as Plasma Enhanced Chemical Vapor Deposition or PECVD for short. On account of the different deposition techniques, the vacuum is interrupted between the various depositions. The layer deposited first, for example the aforementioned aluminum oxide layer, is then exposed to common ambient air for a certain time, before the next layer is deposited in a further vacuum process.

In a semiconductor material, deviations from an ideal crystal lattice, for example the interruption thereof at a surface, incorporations of foreign substances, or the like, may promote or cause a recombination of charge carriers in the semiconductor material. In such cases, reference is usually made to electrically active defects. In principle, electrically active defects may also be present in non-crystalline materials and in certain circumstances may be passivated. In the present case, passivation is understood to mean a reduction in the recombination activity of electrically active defects.

The passivation of surfaces of semiconductor materials generally pursues the aim of reducing a recombination of charge carriers in regions of the semiconductor material close to the surface. Inter alia, this can be effected by what is termed a field effect passivation, in which fixed electrical charges are provided in the applied dielectric layer or the interface thereof with the semiconductor material. A relevant characteristic variable of this type of passivation is the fixed overall charge. In the event of passivation by aluminum oxide-silicon nitride layer stacks, a negative charge is formed at the interface with the semiconductor material, for which reason said layer stack is very readily suitable for the passivation of p-doped regions of semiconductor materials. An alternative passivation mechanism is represented by what is termed chemical passivation, in which an imperfection density at the interface is reduced, said imperfection density often being referred to in English as interface trap density. Such a chemical passivation may be realized, for example, by the accumulation of atomic hydrogen at open bonds located at the surface of the semiconductor material. In the process, the atomic hydrogen saturates said open bonds and in this way passivates the otherwise electrically active defects.

Against the background outlined, the present invention is based on the object of providing a method which allows for a good passivation of surfaces of a semiconductor material with little outlay.

This object is achieved by a method having the features of claim 1.

Furthermore, the present invention is based on the object of providing a semiconductor material with a surface which is passivated with little outlay.

This object is achieved by a semiconductor material having the features of the subordinate independent claim.

Advantageous developments are in each case the subject matter of dependent claims.

The above-described interruption of the vacuum leads to comparatively long treatment periods. After the interruption of the vacuum, the latter firstly has to be built up again. Moreover, the semiconductor materials are regularly reloaded from one coating installation into another coating installation during the interruption of the vacuum. To achieve the above-described objects, attempts were initially made to avoid the interruption of the vacuum. For this purpose, layers of a layer stack were applied with the same coating technology in the same installation. By way of example, a layer stack of an aluminum oxide layer and a silicon nitride layer can be applied in the same installation by means of a plasma-driven vapor deposition (referred to hereinafter for short as PECVD deposition). In the course of corresponding test series, it emerged that the passivation effect turns out to be lower without the interruption of the vacuum. The interruption of the vacuum thus improves the passivating properties of the applied layers or of the applied layer stack. The reasons for this are not yet known. It is possible that air constituents, presumably water, react with one of the layers of the layer stack during the interruption of the vacuum, or said air constituents are incorporated into a layer of the layer stack. In subsequent process steps at temperatures lying above room temperature, such as for example a silicon nitride deposition or a firing step, it appears that reactions take place which lead either to the generation of additional fixed electrical charges or to the saturation of open bonds at the interface with the semiconductor material. A scientific confirmation of these processes is not yet present.

Furthermore, it has been attempted to form the various layers of the layer stack in the same installation, but to vent the installation between the deposition of an aluminum oxide layer and a subsequent deposition of a silicon nitride layer. Compared to the above-described elimination of the interruption of the vacuum, a better passivation effect can be achieved in this way. However, this still remains behind the passivation effect which is established when the semiconductor material is moved completely out of the process tube of a coating installation between the deposition of the aluminum oxide layer and of the silicon nitride layer. In the described case, the venting was effected with common ambient air. Venting with dry compressed air or nitrogen leads to poorer passivation effects.

Against this background, it was possible to consider introducing steam, produced for example by means of a steam generator, into the process tube of a deposition installation used. However, such a procedure is scarcely compatible or compatible only with a very high outlay with a formation of the vacuum required for depositions of dielectric layers. In addition, there is the risk in this procedure that inner walls of a recipient of the deposition installation are covered with an undesirably high quantity of water.

Therefore, for the passivation of a surface of a semiconductor material, it is proposed to form a layer stack which comprises an aluminum oxide layer and an outer coating on the surface of the semiconductor material. The aluminum oxide layer and the outer coating are respectively formed in vacuum processes in which there is a vacuum. The vacuum is maintained between the forming of the aluminum oxide layer and the forming of the outer coating. After the forming of the aluminum oxide layer and before the forming of the outer coating, hydrogen and oxygen are supplied to the aluminum oxide layer formed.

A vacuum for the purposes of the invention is present if the pressure in a process space, for example a process tube, is less than 10 mbar, preferably less than 5 mbar. In the present case, a vacuum process is understood to mean a process carried out under a vacuum. For the purposes of the invention, maintaining of the vacuum is to be understood as meaning that the pressure in the process space is always less than 1100 mbar, preferably always less than 500 mbar and particularly preferably always less than 100 mbar, for a time during which the vacuum is maintained. When maintaining the vacuum, the pressure values of 10 mbar, or preferably 5 mbar, indicated above for the vacuum may occasionally accordingly be exceeded in principle. In an ideal case, however, they are continuously kept at pressures of less than 10 mbar, preferably of less than 5 mbar, since then no extension of the process time whatsoever can arise on account of pumping processes.

The hydrogen and the oxygen, which are supplied to the aluminum oxide layer between the forming of the aluminum oxide layer and the forming of the silicon nitride layer, can be supplied in principle in any desired suitable form. The hydrogen as well as the oxygen can be supplied in particular in a molecularly bound form.

By means of the method described, the process times for the passivation of the surface of the semiconductor material can be reduced with little outlay, since an interruption of the vacuum is not required. Reloading of the semiconductor material from one installation into another can likewise be dispensed with. Nevertheless, it is possible to achieve passivation effects which are equally as good as those achieved in a passivation process with an interruption of the vacuum, in which the aluminum oxide layer is exposed to common ambient air. The very good passivation effect of the above-described method can be attributed predominantly to a very good chemical passivation effect.

In one development, the outer coating comprises one or more layers from a group consisting of a silicon nitride layer, a silicon oxynitride layer and a silicon oxide layer, preferably a silicon nitride layer. These layers have proved to be suitable particularly in the case of semiconductor materials consisting of silicon.

The outer coating advantageously comprises a plurality of layers which are arranged on top of one another. These layers each contain silicon and also in addition nitrogen and/or oxygen. Moreover, said layers comprise different concentrations of silicon, oxygen and/or nitrogen. In other words, this means that one of said layers comprises different concentrations of silicon, nitrogen and/or oxygen compared to the other of said layers. That is to say that the layers which are arranged on top of one another differ at least in the concentration of one of said elements. It is preferable that different concentrations of said elements are present in each of said layers than in the rest of said layers. In practice, outer coatings comprising three layers have proved to be suitable. Outer coatings comprising a silicon oxynitride layer, a first silicon nitride layer arranged thereon and a second silicon nitride layer arranged in turn on the first silicon nitride layer have proved to be particularly suitable, with the first and the second silicon nitride layers having different compositions.

In one embodiment variant, the hydrogen and the oxygen are supplied to the aluminum oxide layer formed in the form of water. Supply of water is equivalent to a supply of moisture. In particular, water can be supplied in a gaseous aggregate state.

The hydrogen and the oxygen are advantageously supplied with the formation of an interim plasma. An interim plasma in this respect is to be understood as meaning a plasma which is formed between the forming of the aluminum oxide layer and the forming of the outer coating. The interim plasma is preferably realized in a PECVD installation.

It has proved to be advantageous to form the interim plasma using nitrous oxide and/or ammonia. The interim plasma is preferably formed using nitrous oxide and ammonia. Very good passivation effects can be achieved in this way.

It is particularly preferable that an interim plasma is formed using nitrous oxide and ammonia and for this purpose a gas mixture of nitrous oxide and gaseous ammonia is provided in a process space. It has been found that in this way the imperfection density at the interface can be reduced by a factor of 2.8 compared to a value which can be realized using a method in which the vacuum is interrupted and the aluminum oxide layer is exposed to common ambient air. The formation of the interim plasma using nitrous oxide and ammonia ultimately leads to an increase in the hydrogen concentration at the semiconductor material-aluminum oxide layer interface. It is not yet known which microscopic process forms the basis for this result. A currently discussed model for explaining the effects provides for a production of OH⁻ ions, this involving released hydrogen which then for its part passivates the interface.

Furthermore, it has been found that an interim plasma formed using nitrous oxide can increase the fixed overall charge at the interface between semiconductor material and aluminum oxide layer. The detailed microscopic process is again not known. One model for explaining this effect may be that the oxygen originating from the nitrous oxide forms AlO₄ complexes, which have a negative charge and therefore lead to a higher number of negative fixed electrical charges at said interface.

In one method variant, the surface of a silicon material is passivated. The method has proved to be particularly suitable in connection with this semiconductor material.

The aluminum oxide layer and the outer coatings are preferably formed by means of a PECVD deposition. This is preferably effected in a tube furnace. In this way, the same proven deposition technology can continuously be used and the interim plasma can be formed in a convenient manner.

The methods described have proved to be particularly suitable for the passivation of a solar cell substrate, preferably for the passivation of the back side thereof. In this respect, the back side of the solar cell substrate is to be understood as meaning that large-area side of the solar cell substrate which, during regular operation of the solar cell manufactured therefrom, is oriented in a manner remote from the incident light. The method according to the invention has proved to be particularly suitable for the production of solar cells of what is termed the PERC type, where PERC stands for Passivated Emitter Rear Cell. In the context of the manufacturing of PERC solar cells with screen printing metallization, a very good passivation of the surface of the solar cell can be realized by means of the method according to the invention. Contact firing or tempering/annealing steps which follow the surface passivation in the solar cell manufacturing process can lead to a further increase in the fixed charge at the interface and to a further reduction in the imperfection density at the interface.

A semiconductor substrate according to the invention comprises a layer stack which is arranged on the surface thereof and which comprises an aluminum oxide layer and an outer coating. An intermediate layer is arranged between the aluminum oxide layer and the outer coating, wherein the intermediate layer is obtainable by treating the aluminum oxide layer by means of a plasma formed using nitrous oxide and ammonia.

In the present sense, a semiconductor substrate is to be understood as meaning any semiconductor material which is suited to being provided with coatings on its surface. The nature of the intermediate layer is still largely unknown to date. In transmission electron microscope micrographs, however, it is identifiable as a contrasting layer, for example as a bright layer, between the aluminum oxide layer and the outer coating.

The described semiconductor substrate has a good surface passivation and can be produced with little outlay. In particular, it can be produced by the method according to the invention.

In one embodiment variant, the outer coating comprises at least one layer from a group consisting of a silicon nitride layer, a silicon oxynitride layer and a silicon oxide layer, preferably a silicon nitride layer. In this way, good surface passivations can be realized.

The outer coating preferably comprises a plurality of layers which are arranged on top of one another. These each contain silicon and also in addition nitrogen and/or oxygen. Said layers comprise different concentrations of silicon, oxygen and/or nitrogen. That is to say that the layers arranged on top of one another differ at least in the concentration of one of said elements. By way of example, a silicon nitride layer, a silicon oxynitride layer and a silicon oxide layer can be provided. In another, preferred example, a silicon oxynitride layer is arranged on the semiconductor substrate, a first silicon nitride layer is arranged on the silicon oxynitride layer, and a second silicon nitride layer is arranged in turn on said first silicon nitride layer, with the first and the second silicon nitride layers having different compositions.

A silicon substrate is particularly preferably provided as the semiconductor substrate. Already very good results could be achieved on this material. In particular, this may be a silicon solar cell substrate, i.e. a silicon substrate from which a silicon solar cell is produced.

In practice, a thickness of 5 nm to 20 nm has proved to be suitable for the aluminum oxide layer, and a thickness of 5 nm to 10 nm has proved to be particularly suitable.

The outer coating preferably has a thickness of 50 nm to 200 nm, with a thickness of 80 nm to 150 nm having proved to be particularly suitable.

Hereinbelow, the invention will be explained in more detail on the basis of figures. Where expedient, elements with an identical action are provided with the same reference signs herein. The invention is not limited to the exemplary embodiments illustrated in the figures—also not with reference to functional features. The description to date and also the following description of the figures contain numerous features which are portrayed in the dependent claims, in some cases combined into groups. However, these features and also all other features disclosed above and in the following description of the figures will also be considered individually and combined into appropriate further combinations by a person skilled in the art. In particular, all of said features can each be combined individually and in any desired suitable combination with the method and/or the semiconductor substrate of the independent claims.

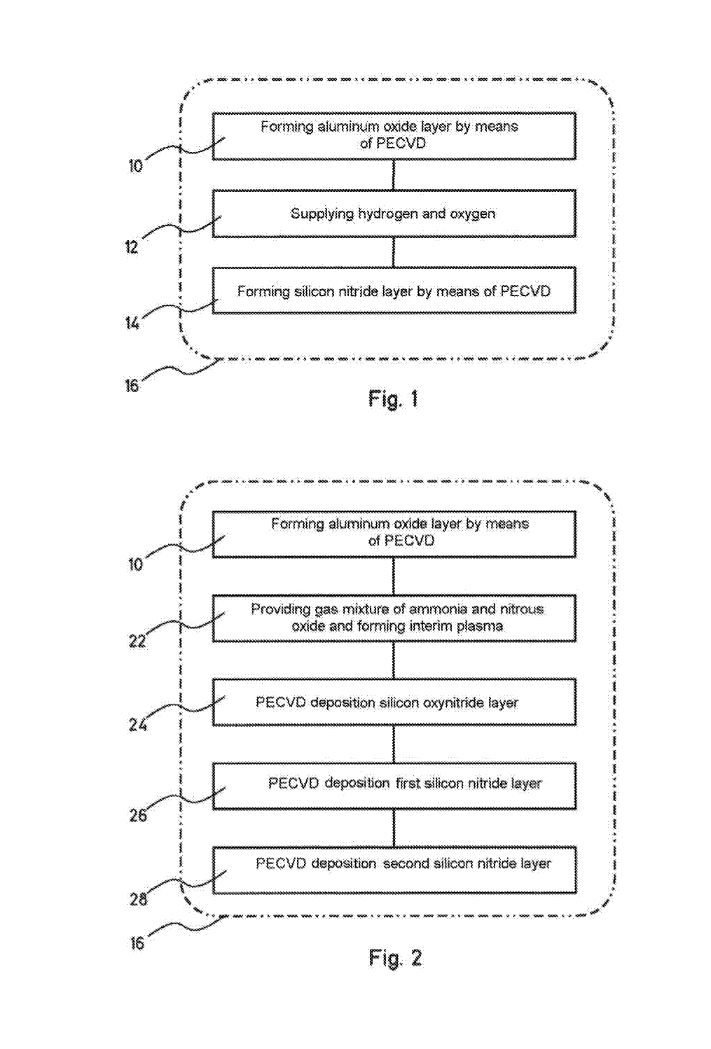

FIG. 1 shows a basic illustration of a first method variant,

FIG. 2 shows a basic illustration of a second method variant,

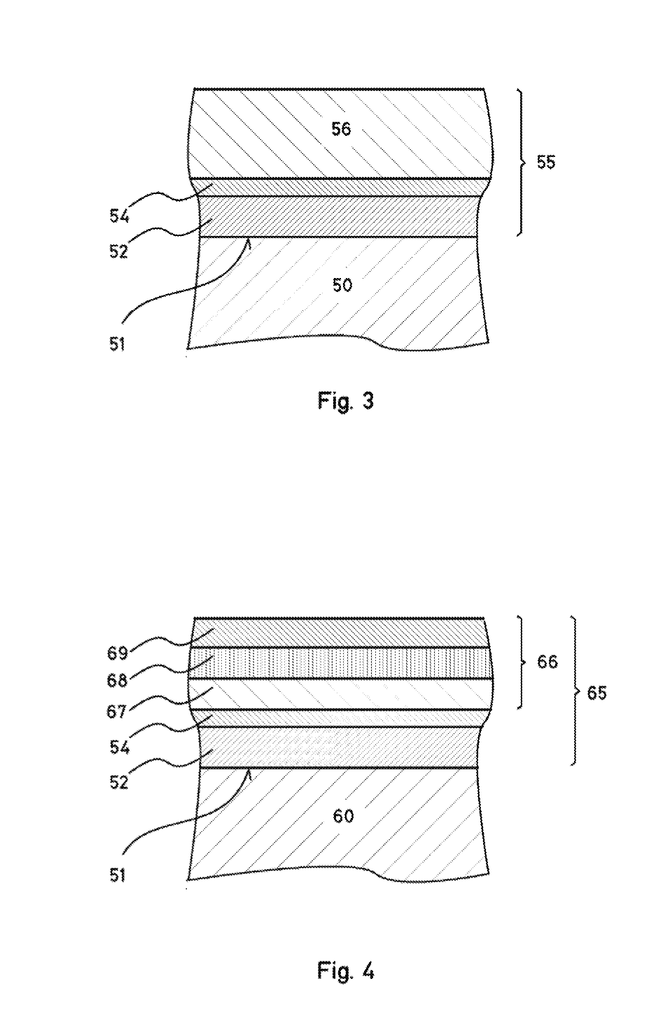

FIG. 3 shows a schematic partial sectional illustration of a first embodiment variant of a semiconductor substrate,

FIG. 4 shows a schematic partial sectional illustration of a second embodiment variant of the semiconductor substrate.

FIG. 1 shows a schematic illustration of a first exemplary embodiment of a method for passivating a surface of a semiconductor substrate. In this exemplary embodiment, a layer stack is formed on a surface of the semiconductor substrate in that firstly an aluminum oxide layer is formed 10 by means of a PECVD deposition. The aluminum oxide layer is formed here in a thickness of 5 nm to 20 nm, preferably of 5 nm to 10 nm.

In addition, hydrogen and oxygen are supplied 12 to the aluminum oxide layer. By way of example, hydrogen and oxygen can be supplied in the form of water. They are preferably supplied with the formation of an interim plasma.

In addition, a silicon nitride layer is formed 14 by means of a PECVD deposition. The thickness of the silicon nitride layer here is 50 nm to 200 nm, with the silicon nitride layer preferably being applied in a thickness of between 80 nm and 150 nm. Both the PECVD deposition of the aluminum oxide layer and also the PECVD deposition of the silicon nitride layer are preferably effected in a tube furnace.

Throughout the method steps outlined to date, a vacuum is maintained 16. In the illustration shown in FIG. 1, this is indicated by a dashed-dotted line.

In the exemplary embodiment shown in FIG. 1, the silicon nitride layer formed represents an outer coating, such that hydrogen and oxygen are supplied 12 to the aluminum oxide layer before the forming 14 of the outer coating. The vacuum is accordingly maintained between the forming 10 of the aluminum oxide layer and the forming 14 of the outer coating.

FIG. 2 illustrates a further method variant on the basis of a basic illustration. In this case, it holds true again that the aluminum oxide layer is firstly formed 10 by means of PECVD deposition. The thicknesses of the aluminum oxide layer are preferably chosen in the same way as in the case of the exemplary embodiment shown in FIG. 1. Before the forming of an outer coating, hydrogen and oxygen are moreover supplied to the aluminum oxide layer. In the exemplary embodiment shown in FIG. 2, this is effected in that a gas mixture of gaseous ammonia and nitrous oxide is provided 22 in a process space and an interim plasma is formed 22.

In addition, an outer coating is formed. For this purpose, a plurality of layers are arranged on top of one another, these together forming the outer coating. In the exemplary embodiment shown in FIG. 4, this is effected by a PECVD deposition of a silicon oxynitride layer 24, a PECVD deposition 26 of a first silicon nitride layer, and a PECVD deposition 28 of a second silicon nitride layer. The first silicon nitride layer here has a different composition to the second silicon nitride layer. Each layer of the outer coating comprises silicon and also in addition either nitrogen or oxygen or both. Moreover, the elements silicon, nitrogen and/or oxygen are present in each layer of the outer coating in different concentrations. The layer thicknesses realized during the silicon oxynitride layer deposition 24, the deposition 26 of the first silicon nitride layer and the deposition 28 of the second silicon nitride layer are chosen in such a way that the overall thickness of these three layers, and therefore the thickness of the outer coating, is 50 nm to 200 nm, preferably 80 nm to 150 nm. In the present exemplary embodiment, the silicon oxynitride layer deposition 24, the deposition 26 of the first silicon nitride layer and also the deposition 28 of the second silicon nitride layer are carried out again in a tube furnace. In the case of a modification of the method as shown in FIG. 2, the deposition 26 of the first silicon nitride layer can be replaced by the deposition of a silicon oxide layer.

Between the forming 10 of the aluminum oxide layer and the silicon oxynitride layer deposition 24, the vacuum is maintained 16 in the sense explained above. In addition, the vacuum is maintained over all of the method steps illustrated in FIG. 2, and therefore a rapid procedure is possible without an interruption of the vacuum and subsequent pumping times for renewed formation of a vacuum.

FIG. 3 shows a schematic partial sectional illustration of a semiconductor substrate, which in the exemplary embodiment shown in FIG. 3 is configured as a silicon solar cell substrate 50. A layer stack 55 is arranged on a surface 51 of the silicon solar cell substrate 50. Said layer stack comprises an aluminum oxide layer 52 and an outer coating 56. An intermediate layer 54 is arranged between the aluminum oxide layer 52 and the outer coating 56. Said intermediate layer 54 is obtainable by treating the aluminum oxide layer 52 by means of a plasma formed using nitrous oxide and ammonia. In particular, the intermediate layer 54 is obtainable by forming 10 the aluminum oxide layer 52 and subsequently providing 22 the gas mixture of ammonia and nitrous oxide and forming 22 an interim plasma as per the method variant illustrated in FIG. 2.

The outer coating 56 is preferably configured as a silicon nitride layer. The thickness thereof is 50 nm to 200 nm and preferably 80 nm to 150 nm. The thickness of the aluminum oxide layer 52 amounts to 5 nm to 20 nm, preferably to 5 nm to 10 nm.

In the case of the exemplary embodiment shown in FIG. 4, a silicon solar cell substrate 60 is once again provided as the semiconductor substrate. The embodiment variant shown in FIG. 4 differs from the exemplary embodiment shown in FIG. 3 in that provision is made of an outer coating 66, which comprises a plurality of layers 67, 68, 69 arranged on top of one another. Analogously to in the exemplary embodiment shown in FIG. 2, one of these layers is a silicon oxynitride layer 67, a further layer is a first silicon nitride layer 68, and the third layer is a second silicon nitride layer 69, with the first silicon nitride layer 68 and the second silicon nitride layer 69 having different compositions. Together with the intermediate layer 54 already explained in conjunction with FIG. 3 and the aluminum oxide layer 52, said layers form a layer stack 65. The thicknesses of the silicon oxynitride layer 67, the first silicon nitride layer 68 and the second silicon nitride layer 69 are in turn chosen in such a manner that their total layer thickness, and thus the thickness of the outer coating, is 50 nm to 200 nm, preferably 80 nm to 150 nm.

One arrives at a further exemplary embodiment by replacing the first silicon nitride layer 68 with a silicon oxide layer in the embodiment variant shown in FIG. 4.

The silicon solar cell substrate 60 shown in FIG. 4 can advantageously be produced by means of the method shown in FIG. 2.

### LIST OF REFERENCE SIGNS

10 Forming aluminum oxide layer by means of PECVD formation
12 Supplying hydrogen and oxygen
14 Forming silicon nitride layer by means of PECVD
16 Maintaining vacuum
22 Providing gas mixture of ammonia and nitrous oxide and forming interim plasma
24 PECVD deposition silicon oxynitride layer
26 PECVD deposition first silicon nitride layer
28 PECVD deposition second silicon nitride layer
50 Silicon solar cell substrate
51 Surface
52 Aluminum oxide layer
54 Intermediate layer
55 Layer stack
56 Outer coating
60 Silicon solar cell substrate
65 Layer stack
66 Outer coating
67 Silicon oxynitride layer
68 First silicon nitride layer
69 Second silicon nitride layer

1-18. (canceled)

19. A method for passivating a surface of a semiconductor material, the method comprising the following steps:
forming a layer stack including an aluminum oxide layer and an outer coating on the surface of the semiconductor material;
forming the aluminum oxide layer and the outer coating in respective vacuum processes providing a vacuum;
maintaining the vacuum between the forming of the aluminum oxide layer and the forming of the outer coating; and
supplying hydrogen and oxygen to the formed aluminum oxide layer after the forming of the aluminum oxide layer and before the forming of the outer coating.

20. The method according to claim 19, which further comprises providing the outer coating as at least one layer selected from the group consisting of a silicon nitride layer, a silicon oxynitride layer and a silicon oxide layer.

21. The method according to claim 20, which further comprises providing the silicon oxide layer as a silicon nitride layer.

22. The method according to claim 19, which further comprises providing the outer coating as a plurality of layers disposed on top of one another, each of the plurality of layers containing silicon and at least one of nitrogen or oxygen, and the plurality of layers having different concentrations of at least one of silicon, oxygen or nitrogen.

23. The method according to claim 19, which further comprises carrying out the step of supplying the hydrogen and the oxygen to the aluminum oxide layer as water.

24. The method according to claim 19, which further comprises carrying out the step of supplying the hydrogen and the oxygen with a formation of an interim plasma.

25. The method according to claim 24, which further comprises forming the interim plasma by using at least one of nitrous oxide or ammonia.

26. The method according to claim 24, which further comprises forming the interim plasma by using nitrous oxide and ammonia.

27. The method according to claim 26, which further comprises providing a gas mixture of nitrous oxide and gaseous ammonia in a process space.

28. The method according to claim 19, which further comprises passivating a surface of a silicon material as the semiconductor material.

29. The method according to claim 19, which further comprises forming the aluminum oxide layer and the outer coating by a plasma-driven vapor deposition.

30. The method according to claim 29, which further comprises carrying out the plasma-driven vapor deposition in a tube furnace.

31. The method according to claim 19, which further comprises forming the aluminum oxide layer with a thickness of 5 nm to 20 nm.

32. The method according to claim 19, which further comprises forming the aluminum oxide layer with a thickness of 5 nm to 10 nm.

33. The method according to claim 19, which further comprises forming the outer coating with a thickness of 50 nm to 200 nm.

34. The method according to claim 19, which further comprises forming the outer coating with a thickness of 80 nm to 150 nm.

35. The method according to claim 19, which further comprises passivating a surface of a solar cell substrate as the semiconductor material.

36. The method according to claim 19, which further comprises passivating a back side surface of a solar cell substrate as the semiconductor material.

37. A semiconductor substrate, comprising:
a surface of the semiconductor substrate;
a layer stack disposed on said surface, said layer stack including an aluminum oxide layer and an outer coating; and
an intermediate layer disposed between said aluminum oxide layer and said outer coating;
said intermediate layer having characteristics of having been formed by treating said aluminum oxide layer with a plasma formed by using nitrous oxide and ammonia.

38. The semiconductor substrate according to claim 37, wherein said outer coating includes at least one layer selected from the group consisting of a silicon nitride layer, a silicon oxynitride layer and a silicon oxide layer.

39. The semiconductor substrate according to claim 38, wherein said silicon oxide layer is a silicon nitride layer.

40. The semiconductor substrate according to claim 37, wherein said outer coating includes a plurality of layers disposed on top of one another, each of said plurality of layers contains silicon and at least one of nitrogen or oxygen, and said plurality of layers have different concentrations of at least one of silicon, oxygen or nitrogen.

41. The semiconductor substrate according to claim 37, wherein the semiconductor substrate is a silicon substrate.

42. The semiconductor substrate according to claim 37, wherein said aluminum oxide layer has a thickness of 5 nm to 20 nm.

43. The semiconductor substrate according to claim 37, wherein said aluminum oxide layer has a thickness of 5 nm to 10 nm.

44. The semiconductor substrate according to claim 37, wherein said outer coating has a thickness of 50 nm to 200 nm.

45. The semiconductor substrate according to claim 37, wherein said outer coating has a thickness of 80 nm to 150 mm.
